(19) United States
(12) Patent Application Publication
(10) Pub. No.: US 2025/0253503 A1
(43) Pub. Date: Aug. 7, 2025

(54) BATTERY AND ELECTRONIC DEVICE INCLUDING SAME

(71) Applicant: Samsung Electronics Co., Ltd., Suwon-si (KR)

(72) Inventors: Yeonil LEE, Suwon-si (KR); Sinyoung JUNG, Suwon-si (KR)

(21) Appl. No.: 19/186,048

(22) Filed: Apr. 22, 2025

Related U.S. Application Data
(63) Continuation of application No. PCT/KR2023/017731, filed on Nov. 7, 2023.

(30) Foreign Application Priority Data
Nov. 11, 2022 (KR) 10-2022-0150573
Dec. 28, 2022 (KR) 10-2022-0187257

(51) Int. Cl. H01M 50/534; H01M 50/466; H01M 50/491

(52) U.S. Cl. CPC H01M 50/534; H01M 50/466; H01M 50/491; H01M 2220/30

(57) ABSTRACT

An electronic device is provided. The electronic device includes a processor, and a battery configured to supply power to the processor, wherein the battery includes a first electrode, a second electrode, a separator configured to prevent contact between the first electrode and the second electrode, a first tab connected to the first electrode, and an adhesive disposed on at least a portion of the first tab, wherein the first electrode includes a first substrate, and a first mixture surrounding at least a portion of the first substrate and spaced apart from the adhesive, and wherein the adhesive is located between a coupling portion of the first tab and the first mixture.

### CROSS-REFERENCE TO RELATED APPLICATION(S)

This application is a continuation application, claiming priority under 35 U.S.C. § 365 (c), of an International application No. PCT/KR2023/017731, filed on Nov. 7, 2023, which is based on and claims the benefit of a Korean patent application number 10-2022-0150573, filed on Nov. 11, 2022, in the Korean Intellectual Property Office, and of a Korean patent application number 10-2022-0187257, filed on Dec. 28, 2022, in the Korean Intellectual Property Office, the disclosure of each of which is incorporated by reference herein in its entirety.

### BACKGROUND

### 1. Field

The disclosure relates to a battery and an electronic device including the battery.

### 2. Description of Related Art

Along with the development of information and communication technology and semiconductor technology, various functions are integrated into a single portable electronic device. For example, in addition to a communication function, an entertainment function such as games, a multimedia function such as music/video playback, a communication and security function for mobile banking, or a function such as schedule management or an electronic wallet may be implemented in an electronic device. Such an electronic device is being miniaturized so that a user may conveniently carry it.

As the use of electronic devices becomes more common, user demands for portability and usability of electronic devices may increase. In response to these user demands, for example, secondary batteries that are chargeable or dischargeable are used as power sources for electronic devices.

The above information is presented as background information only to assist with an understanding of the disclosure. No determination has been made, and no assertion is made, as to whether any of the above might be applicable as prior art with regard to the disclosure.

### SUMMARY

Aspects of the disclosure are to address at least the above-mentioned problems and/or disadvantages and to provide at least the advantages described below. Accordingly, an aspect of the disclosure is to provide a battery and an electronic device including the battery.

Additional aspects will be set forth in part in the description which follows and, in part, will be apparent from the description, or may be learned by practice of the presented embodiments.

In accordance with an aspect of the disclosure, an electronic device is provided. The electronic device includes a processor, and a battery configured to supply power to the processor, wherein the battery includes a first electrode, a second electrode, a separator configured to prevent contact between the first electrode and the second electrode, a first tab connected to the first electrode, and an adhesive disposed on at least a portion of the first tab, wherein the first electrode includes a first substrate, and a first mixture surrounding at least a portion of the first substrate and spaced apart from the adhesive, and wherein the adhesive is located between a coupling portion of the first tab and the first mixture.

In accordance with another aspect of the disclosure, a battery is provided. The battery includes a first electrode, a second electrode, a separator configured to prevent contact between the first electrode and the second electrode, a first tab connected to the first electrode, and an adhesive disposed on at least a portion of the first tab, wherein the first electrode includes a first substrate, and a first mixture surrounding at least a portion of the first substrate and spaced apart from the adhesive, and wherein the adhesive is located between a coupling portion of the first tab and the first mixture.

Other aspects, advantages, and salient features of the disclosure will become apparent to those skilled in the art from the following detailed description, which, taken in conjunction with the annexed drawings, discloses various embodiments of the disclosure.

### BRIEF DESCRIPTION OF THE DRAWINGS

The above and other aspects, features, and advantages of certain embodiments of the disclosure will be more apparent from the following description taken in conjunction with the accompanying drawings, in which:

FIG. 1 is a block diagram illustrating an electronic device in a network environment according to an embodiment of the disclosure;

FIG. 2 is a front perspective view illustrating an electronic device according to an embodiment of the disclosure;

FIG. 3 is a rear perspective view illustrating an electronic device according to an embodiment of the disclosure;

FIG. 4 is an exploded perspective view illustrating an electronic device according to an embodiment of the disclosure;

FIG. 5 is a schematic diagram illustrating a battery according to an embodiment of the disclosure;

FIG. 6 is a front view illustrating a battery according to an embodiment of the disclosure;

FIG. 7 is a side view illustrating a battery according to an embodiment of the disclosure;

FIGS. 8A and 8B are side views illustrating a battery including an adhesive according to various embodiments of the disclosure;

FIG. 9 is a side view illustrating a battery including a plurality of adhesives according to an embodiment of the disclosure; and

FIGS. 10 and 11 are diagrams illustrating a process of manufacturing a battery according to various embodiments of the disclosure.

The same reference numerals are used to represent the same elements throughout the drawings.

### DETAILED DESCRIPTION

The following description with reference to the accompanying drawings is provided to assist in a comprehensive understanding of various embodiments of the disclosure as defined by the claims and their equivalents. It includes various specific details to assist in that understanding but these are to be regarded as merely exemplary. Accordingly, those of ordinary skill in the art will recognize that various changes and modifications of the various embodiments described herein can be made without departing from the scope and spirit of the disclosure. In addition, descriptions of well-known functions and constructions may be omitted for clarity and conciseness.

The terms and words used in the following description and claims are not limited to the bibliographical meanings, but, are merely used by the inventor to enable a clear and consistent understanding of the disclosure. Accordingly, it should be apparent to those skilled in the art that the following description of various embodiments of the disclosure is provided for illustration purpose only and not for the purpose of limiting the disclosure as defined by the appended claims and their equivalents.

It is to be understood that the singular forms “a,” “an,” and “the” include plural referents unless the context clearly dictates otherwise. Thus, for example, reference to “a component surface” includes reference to one or more of such surfaces.

It should be appreciated that the blocks in each flowchart and combinations of the flowcharts may be performed by one or more computer programs which include instructions. The entirety of the one or more computer programs may be stored in a single memory device or the one or more computer programs may be divided with different portions stored in different multiple memory devices.

Any of the functions or operations described herein can be processed by one processor or a combination of processors. The one processor or the combination of processors is circuitry performing processing and includes circuitry like an application processor (AP, e.g. a central processing unit (CPU)), a communication processor (CP, e.g., a modem), a graphics processing unit (GPU), a neural processing unit (NPU) (e.g., an artificial intelligence (AI) chip), a wireless fidelity (Wi-Fi) chip, a Bluetooth® chip, a global positioning system (GPS) chip, a near field communication (NFC) chip, connectivity chips, a sensor controller, a touch controller, a finger-print sensor controller, a display driver integrated circuit (IC), an audio CODEC chip, a universal serial bus (USB) controller, a camera controller, an image processing IC, a microprocessor unit (MPU), a system on chip (SoC), an IC, or the like.

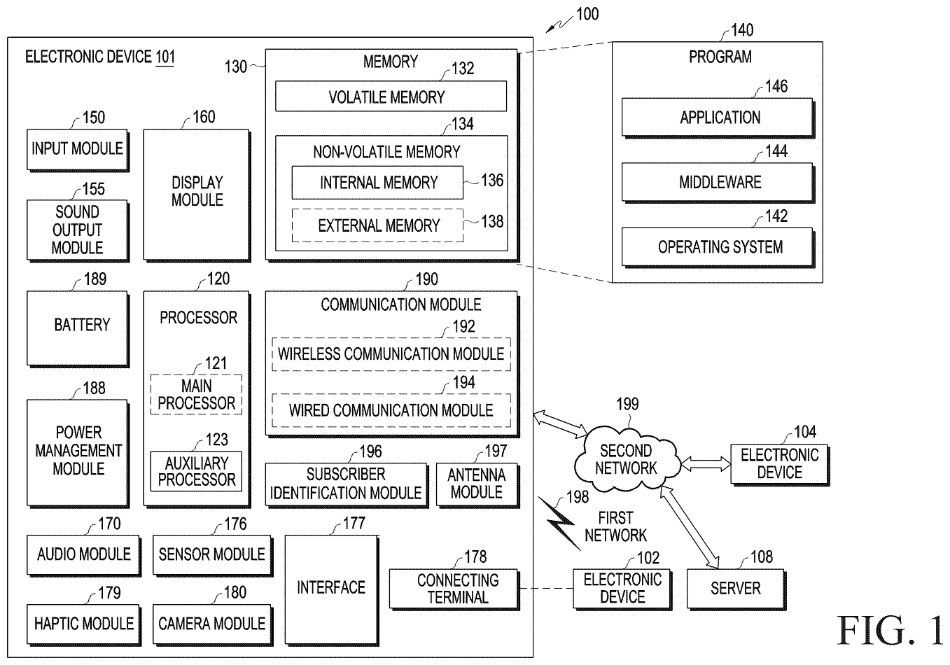

FIG. 1 is a block diagram illustrating an electronic device in a network environment according to an embodiment of the disclosure.

Referring to FIG. 1, an electronic device 101 in a network environment 100 may communicate with an electronic device 102 via a first network 198 (e.g., a short-range wireless communication network), or an electronic device 104 or a server 108 via a second network 199 (e.g., a long-range wireless communication network). According to an embodiment, the electronic device 101 may communicate with the electronic device 104 via the server 108. According to an embodiment, the electronic device 101 may include a processor 120, memory 130, an input module 150, a sound output module 155, a display module 160, an audio module 170, a sensor module 176, an interface 177, a connecting terminal 178, a haptic module 179, a camera module 180, a power management module 188, a battery 189, a communication module 190, a subscriber identification module (SIM) 196, or an antenna module 197. In some embodiments, at least one of the components (e.g., the connecting terminal 178) may be omitted from the electronic device 101, or one or more other components may be added in the electronic device 101. In some embodiments, some of the components (e.g., the sensor module 176, the camera module 180, or the antenna module 197) may be implemented as a single component (e.g., the display module 160).

The processor 120 may execute, for example, software (e.g., a program 140) to control at least one other component (e.g., a hardware or software component) of the electronic device 101 coupled with the processor 120, and may perform various data processing or computation. According to an embodiment, as at least part of the data processing or computation, the processor 120 may store a command or data received from another component (e.g., the sensor module 176 or the communication module 190) in volatile memory 132, process the command or the data stored in the volatile memory 132, and store resulting data in non-volatile memory 134. According to an embodiment, the processor 120 may include a main processor 121 (e.g., a central processing unit (CPU) or an application processor (AP)), or an auxiliary processor 123 (e.g., a graphics processing unit (GPU), a neural processing unit (NPU), an image signal processor (ISP), a sensor hub processor, or a communication processor (CP)) that is operable independently from, or in conjunction with, the main processor 121. For example, when the electronic device 101 includes the main processor 121 and the auxiliary processor 123, the auxiliary processor 123 may be adapted to consume less power than the main processor 121, or to be specific to a specified function. The auxiliary processor 123 may be implemented as separate from, or as part of the main processor 121.

The auxiliary processor 123 may control at least some of functions or states related to at least one component (e.g., the display module 160, the sensor module 176, or the communication module 190) among the components of the electronic device 101, instead of the main processor 121 while the main processor 121 is in an inactive (e.g., sleep) state, or together with the main processor 121 while the main processor 121 is in an active state (e.g., executing an application). According to an embodiment, the auxiliary processor 123 (e.g., an image signal processor or a communication processor) may be implemented as part of another component (e.g., the camera module 180 or the communication module 190) functionally related to the auxiliary processor 123. According to an embodiment, the auxiliary processor 123 (e.g., the neural processing unit) may include a hardware structure specified for artificial intelligence model processing. An artificial intelligence model may be generated by machine learning. Such learning may be performed, e.g., by the electronic device 101 where the artificial intelligence is performed or via a separate server (e.g., the server 108). Learning algorithms may include, but are not limited to, e.g., supervised learning, unsupervised learning, semi-supervised learning, or reinforcement learning. The artificial intelligence model may include a plurality of artificial neural network layers. The artificial neural network may be a deep neural network (DNN), a convolutional neural network (CNN), a recurrent neural network (RNN), a restricted boltzmann machine (RBM), a deep belief network (DBN), a bidirectional recurrent deep neural network (BRDNN), deep Q-network or a combination of two or more thereof but is not limited thereto. The artificial intelligence model may, additionally or alternatively, include a software structure other than the hardware structure.

The memory 130 may store various data used by at least one component (e.g., the processor 120 or the sensor module 176) of the electronic device 101. The various data may include, for example, software (e.g., the program 140) and input data or output data for a command related thereto. The memory 130 may include the volatile memory 132 or the non-volatile memory 134.

The program 140 may be stored in the memory 130 as software, and may include, for example, an operating system (OS) 142, middleware 144, or an application 146.

The input module 150 may receive a command or data to be used by another component (e.g., the processor 120) of the electronic device 101, from the outside (e.g., a user) of the electronic device 101. The input module 150 may include, for example, a microphone, a mouse, a keyboard, a key (e.g., a button), or a digital pen (e.g., a stylus pen).

The sound output module 155 may output sound signals to the outside of the electronic device 101. The sound output module 155 may include, for example, a speaker or a receiver. The speaker may be used for general purposes, such as playing multimedia or playing record. The receiver may be used for receiving incoming calls. According to an embodiment, the receiver may be implemented as separate from, or as part of the speaker.

The display module 160 may visually provide information to the outside (e.g., a user) of the electronic device 101. The display module 160 may include, for example, a display, a hologram device, or a projector and control circuitry to control a corresponding one of the display, hologram device, and projector. According to an embodiment, the display module 160 may include a touch sensor adapted to detect a touch, or a pressure sensor adapted to measure the strength of force incurred by the touch.

The audio module 170 may convert a sound into an electrical signal and vice versa. According to an embodiment, the audio module 170 may obtain the sound via the input module 150, or output the sound via the sound output module 155 or a headphone of an external electronic device (e.g., the electronic device 102) (e.g., a speaker or headphone) directly (e.g., wiredly) or wirelessly coupled with the electronic device 101.

The sensor module 176 may detect an operational state (e.g., power or temperature) of the electronic device 101 or an environmental state (e.g., a state of a user) external to the electronic device 101, and then generate an electrical signal or data value corresponding to the detected state. According to an embodiment, the sensor module 176 may include, for example, a gesture sensor, a gyro sensor, an atmospheric pressure sensor, a magnetic sensor, an acceleration sensor, a grip sensor, a proximity sensor, a color sensor, an infrared (IR) sensor, a biometric sensor, a temperature sensor, a humidity sensor, or an illuminance sensor.

The interface 177 may support one or more specified protocols to be used for the electronic device 101 to be coupled with the external electronic device (e.g., the electronic device 102) directly (e.g., wiredly) or wirelessly. According to an embodiment, the interface 177 may include, for example, a high definition multimedia interface (HDMI), a universal serial bus (USB) interface, a secure digital (SD) card interface, or an audio interface.

A connecting terminal 178 may include a connector via which the electronic device 101 may be physically connected with the external electronic device (e.g., the electronic device 102). According to an embodiment, the connecting terminal 178 may include, for example, a HDMI connector, a USB connector, a SD card connector, or an audio connector (e.g., a headphone connector).

The haptic module 179 may convert an electrical signal into a mechanical stimulus (e.g., a vibration or a movement) or electrical stimulus which may be recognized by a user via his tactile sensation or kinesthetic sensation. According to an embodiment, the haptic module 179 may include, for example, a motor, a piezoelectric element, or an electric stimulator.

The camera module 180 may capture a still image or moving images. According to an embodiment, the camera module 180 may include one or more lenses, image sensors, image signal processors, or flashes.

The power management module 188 may manage power supplied to the electronic device 101. According to an embodiment, the power management module 188 may be implemented as at least part of, for example, a power management integrated circuit (PMIC).

The battery 189 may supply power to at least one component of the electronic device 101. According to an embodiment, the battery 189 may include, for example, a primary cell which is not rechargeable, a secondary cell which is rechargeable, or a fuel cell.

The communication module 190 may support establishing a direct (e.g., wired) communication channel or a wireless communication channel between the electronic device 101 and the external electronic device (e.g., the electronic device 102, the electronic device 104, or the server 108) and performing communication via the established communication channel. The communication module 190 may include one or more communication processors that are operable independently from the processor 120 (e.g., the application processor (AP)) and supports a direct (e.g., wired) communication or a wireless communication. According to an embodiment, the communication module 190 may include a wireless communication module 192 (e.g., a cellular communication module, a short-range wireless communication module, or a global navigation satellite system (GNSS) communication module) or a wired communication module 194 (e.g., a local area network (LAN) communication module or a power line communication (PLC) module). A corresponding one of these communication modules may communicate with the external electronic device via the first network 198 (e.g., a short-range communication network, such as Bluetooth™ wireless-fidelity (Wi-Fi) direct, or infrared data association (IrDA)) or the second network 199 (e.g., a long-range communication network, such as a legacy cellular network, a fifth generation (5G) network, a next-generation communication network, the Internet, or a computer network (e.g., LAN or wide area network (WAN)). These various types of communication modules may be implemented as a single component (e.g., a single chip), or may be implemented as multi components (e.g., multi chips) separate from each other. The wireless communication module 192 may identify and authenticate the electronic device 101 in a communication network, such as the first network 198 or the second network 199, using subscriber information (e.g., international mobile subscriber identity (IM SI)) stored in the subscriber identification module 196.

The wireless communication module 192 may support a 5G network, after a fourth generation (4G) network, and next-generation communication technology, e.g., new radio (NR) access technology. The NR access technology may support enhanced mobile broadband (eM BB), massive machine type communications (mM TC), or ultra-reliable and low-latency communications (URLLC). The wireless communication module 192 may support a high-frequency band (e.g., the millimeter wave (mmWave) band) to achieve, e.g., a high data transmission rate. The wireless communication module 192 may support various technologies for securing performance on a high-frequency band, such as, e.g., beamforming, massive multiple-input and multiple-output (massive MIMO), full dimensional MIMO (FD-MIMO), array antenna, analog beam-forming, or large scale antenna. The wireless communication module 192 may support various requirements specified in the electronic device 101, an external electronic device (e.g., the electronic device 104), or a network system (e.g., the second network 199). According to an embodiment, the wireless communication module 192 may support a peak data rate (e.g., 20 Gbps or more) for implementing eMBB, loss coverage (e.g., 164 dB or less) for implementing mM TC, or U-plane latency (e.g., 0.5 ms or less for each of downlink (DL) and uplink (UL), or a round trip of 1 ms or less) for implementing URLLC.

The antenna module 197 may transmit or receive a signal or power to or from the outside (e.g., the external electronic device) of the electronic device 101. According to an embodiment, the antenna module 197 may include an antenna including a radiating element composed of a conductive material or a conductive pattern formed in or on a substrate (e.g., a printed circuit board (PCB)). According to an embodiment, the antenna module 197 may include a plurality of antennas (e.g., array antennas). In such a case, at least one antenna appropriate for a communication scheme used in the communication network, such as the first network 198 or the second network 199, may be selected, for example, by the communication module 190 (e.g., the wireless communication module 192) from the plurality of antennas. The signal or the power may then be transmitted or received between the communication module 190 and the external electronic device via the selected at least one antenna. According to an embodiment, another component (e.g., a radio frequency integrated circuit (RFIC)) other than the radiating element may be additionally formed as part of the antenna module 197.

According to various embodiments, the antenna module 197 may form an mmWave antenna module. According to an embodiment, the mmWave antenna module may include a printed circuit board, a RFIC disposed on a first surface (e.g., the bottom surface) of the printed circuit board, or adjacent to the first surface and capable of supporting a designated high-frequency band (e.g., the mmWave band), and a plurality of antennas (e.g., array antennas) disposed on a second surface (e.g., the top or a side surface) of the printed circuit board, or adjacent to the second surface and capable of transmitting or receiving signals of the designated high-frequency band.

At least some of the above-described components may be coupled mutually and communicate signals (e.g., commands or data) therebetween via an inter-peripheral communication scheme (e.g., a bus, general purpose input and output (GPIO), serial peripheral interface (SPI), or mobile industry processor interface (MIPI)).

According to an embodiment, commands or data may be transmitted or received between the electronic device 101 and the external electronic device 104 via the server 108 coupled with the second network 199. Each of the electronic devices 102 or 104 may be a device of a same type as, or a different type, from the electronic device 101. According to an embodiment, all or some of operations to be executed at the electronic device 101 may be executed at one or more of the external electronic devices 102 or 104 or server 108. For example, if the electronic device 101 should perform a function or a service automatically, or in response to a request from a user or another device, the electronic device 101, instead of, or in addition to, executing the function or the service, may request the one or more external electronic devices to perform at least part of the function or the service. The one or more external electronic devices receiving the request may perform the at least part of the function or the service requested, or an additional function or an additional service related to the request, and transfer an outcome of the performing to the electronic device 101. The electronic device 101 may provide the outcome, with or without further processing of the outcome, as at least part of a reply to the request. To that end, a cloud computing, distributed computing, mobile edge computing (MEC), or client-server computing technology may be used, for example. The electronic device 101 may provide ultra low-latency services using, e.g., distributed computing or mobile edge computing. In another embodiment, the external electronic device 104 may include an internet-of-things (IoT) device. The server 108 may be an intelligent server using machine learning and/or a neural network. According to an embodiment, the external electronic device 104 or the server 108 may be included in the second network 199. The electronic device 101 may be applied to intelligent services (e.g., smart home, smart city, smart car, or healthcare) based on 5G communication technology or IoT-related technology.

The electronic device according to various embodiments may be one of various types of electronic devices. The electronic devices may include, for example, a portable communication device (e.g., a smartphone), a computer device, a portable multimedia device, a portable medical device, a camera, a wearable device, or a home appliance. According to an embodiment of the disclosure, the electronic devices are not limited to those described above.

It should be appreciated that various embodiments of the disclosure and the terms used therein are not intended to limit the technological features set forth herein to particular embodiments and include various changes, equivalents, or replacements for a corresponding embodiment. With regard to the description of the drawings, similar reference numerals may be used to refer to similar or related elements. As used herein, each of such phrases as “A or B”, “at least one of A and B”, “at least one of A or B”, “A, B, or C”, “at least one of A, B, and C”, and “at least one of A, B, or C”, may include any one of, or all possible combinations of the items enumerated together in a corresponding one of the phrases. As used herein, such terms as “1^{st}” and “2^{nd}”, or “first” and “second” may be used to simply distinguish a corresponding component from another, and does not limit the components in other aspect (e.g., importance or order). It is to be understood that if an element (e.g., a first element) is referred to, with or without the term “operatively” or “communicatively”, as “coupled with”, “coupled to”, “connected with”, or “connected to” another element (e.g., a second element), it means that the element may be coupled with the other element directly (e.g., wiredly), wirelessly, or via a third element.

As used in connection with various embodiments of the disclosure, the term “module” may include a unit implemented in hardware, software, or firmware, and may interchangeably be used with other terms, for example, logic, logic block, part, or circuitry. A module may be a single integral component, or a minimum unit or part thereof, adapted to perform one or more functions. For example, according to an embodiment, the module may be implemented in a form of an application-specific integrated circuit (A SIC).

An embodiment of the disclosure may be implemented as software (e.g., the program 140) including one or more instructions that are stored in a storage medium (e.g., internal memory 136 or external memory 138) that is readable by a machine (e.g., the electronic device 101). For example, a processor (e.g., the processor 120) of the machine (e.g., the electronic device 101) may invoke at least one of the one or more instructions stored in the storage medium, and execute it, with or without using one or more other components under the control of the processor. This allows the machine to be operated to perform at least one function according to the at least one instruction invoked. The one or more instructions may include a code generated by a complier or a code executable by an interpreter. The storage medium readable by the machine may be provided in the form of a non-transitory storage medium. Wherein, the term “non-transitory”simply means that the storage medium is a tangible device, and does not include a signal (e.g., an electromagnetic wave), but this term does not differentiate between where data is semi-permanently stored in the storage medium and where the data is temporarily stored in the storage medium.

According to various embodiments, each component (e.g., a module or a program) of the above-described components may include a single entity or multiple entities, and some of the multiple entities may be separately disposed in different components. According to various embodiments, one or more of the above-described components may be omitted, or one or more other components may be added. Alternatively or additionally, a plurality of components (e.g., modules or programs) may be integrated into a single component. In such a case, according to various embodiments, the integrated component may still perform one or more functions of each of the plurality of components in the same or similar manner as they are performed by a corresponding one of the plurality of components before the integration. According to various embodiments, operations performed by the module, the program, or another component may be carried out sequentially, in parallel, repeatedly, or heuristically, or one or more of the operations may be executed in a different order or omitted, or one or more other operations may be added.

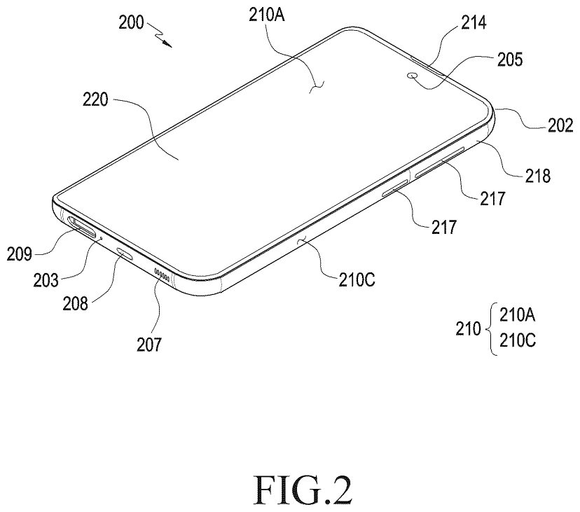

FIG. 2 is a front perspective view illustrating an electronic device according to an embodiment of the disclosure.

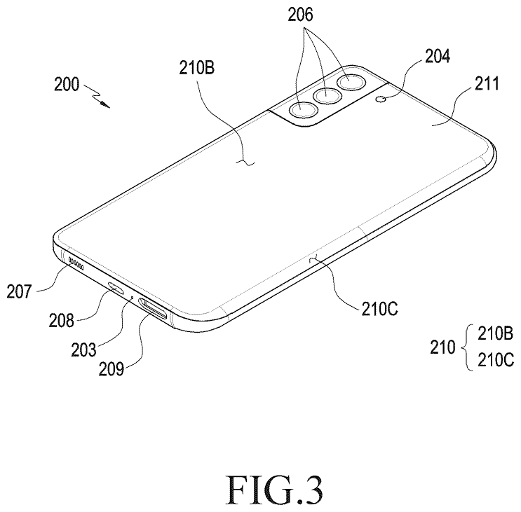

FIG. 3 is a rear perspective view illustrating an electronic device according to an embodiment of the disclosure.

Referring to FIGS. 2 and 3, an electronic device 200 (e.g., the electronic device of FIG. 1) according to an embodiment may include a housing 210 which includes a front surface 210A, a rear surface 210B, and a side surface 210C surrounding a space between the front surface 210A and the rear surface 210B. In another embodiment (not shown), the housing 210 may refer to a structure that forms a portion of the front surface 210A of FIG. 2, the rear surface 210B of FIG. 3, and the side surface 210C. For example, the housing 210 may include a front plate 202 and a rear plate 211. According to an embodiment, at least a portion of the front surface 210A may be formed by the front plate 202 (e.g., a glass plate or polymer plate including various coating layers) at least a portion of which is substantially transparent. The rear plate 211 may be formed of, for example, glass, ceramic, a polymer, a metal (e.g., titanium (Ti), stainless steel (STS), aluminum (Al), and/or magnesium (Mg)), or a combination of at least two of these materials. The side surface 210C may be coupled to the front plate 202 and the rear plate 211 and formed by a side bezel structure (or ‘side member’) 218 including a metal and/or a polymer. In some embodiments, the rear plate 211 and the side bezel structure 218 may be integrally formed and include the same material (e.g., glass, a metal material such as aluminum, or ceramic). In another embodiment, the front surface 210A and/or the front plate 202 may be interpreted as a portion of a display 220.

According to an embodiment, the electronic device 200 may include at least one of the display 220, audio modules 203, 207, and 214 (e.g., the audio module 170 of FIG. 1), a sensor module (e.g., the sensor module 176 of FIG. 1), camera modules 205 and 206 (e.g., the camera module 180 of FIG. 1), key input devices 217 (e.g., the input module 150 of FIG. 1), or connector holes 208 and 209 (e.g., the connecting terminal 178 of FIG. 1). In some embodiment, the electronic device 200 may not be provided with at least one (e.g., the connector hole 209) of the components or may additionally include other components. According to an embodiment, the display 220 may be visually exposed, for example, through a substantial portion of the front plate 202.

According to an embodiment, a surface (or the front plate 202) of the housing 210 may include a screen display area formed by visual exposure of the display 220. For example, the screen display area may include the front surface 210A.

According to an embodiment, a recess or an opening may be formed in a portion of the screen display area (e.g., the front surface 210A) of the display 220, and at least one of the audio module 214, a sensor module (not shown), a light emitting element (not shown), or the camera module 205, which is aligned with the recess or the opening, may be included. In another embodiment (not shown), at least one of the audio module 214, the sensor module (not shown), the camera module 205, a fingerprint sensor (not shown), or the light emitting element (not shown) may be included on the rear surface of the screen display area of the display 220.

According to an embodiment, the display 220 may be incorporated with or disposed adjacent to a touch sensing circuit, a pressure sensor capable of measuring the intensity (pressure) of a touch, and/or a digitizer that detects a magnetic field-based stylus pen.

According to an embodiment, the audio modules 203, 207, and 214 may include, for example, a microphone hole 203 and speaker holes 207 and 214. A microphone for obtaining an external sound may be disposed in the microphone hole 203, and in an embodiment, a plurality of microphones may be disposed to detect the direction of a sound. The speaker holes 207 and 214 may include an external speaker hole 207 and a receiver hole 214 for calls. In an embodiment, the speaker holes 207 and 214 and the microphone hole 203 may be implemented as a single hole, or a speaker (e.g., a piezo speaker) may be included without the speaker holes 207 and 214.

According to an embodiment, the sensor module (not shown) may generate an electrical signal or data value corresponding to an internal operation state of the electronic device 101 or an external environmental state. The sensor module (not shown) may include, for example, a first sensor module (not shown) (e.g., a proximity sensor) and/or a second sensor module (not shown) (e.g., a fingerprint sensor), disposed on the front surface 210A of the housing 210. The sensor module (not shown) may include a third sensor module (not shown) (e.g., a HRM sensor) and/or a fourth sensor module (not shown) (e.g., a fingerprint sensor), disposed on the rear surface 210B of the housing 210. In some embodiments (not shown), the fingerprint sensor may be disposed on the rear surface 210B as well as on the front surface 210A (e.g., the display 220) of the housing 210. The electronic device 101 may further include a sensor module which is not shown, for example, at least one of a gesture sensor, a gyro sensor, a barometric pressure sensor, a magnetic sensor, an acceleration sensor, a grip sensor, a color sensor, an infrared (IR) sensor, a biometric sensor, a temperature sensor, a humidity sensor, or an illuminance sensor (not shown).

According to an embodiment, the camera modules 205 and 206 may include a front camera module 205 disposed on the front surface 210A of the electronic device 200, and a rear camera module 206 and/or a flash 204 disposed on the rear surface 210B of the electronic device 200. The camera modules 205 and 206 may include one or more lenses, an image sensor, and/or an image signal processor. The flash 204 may include, for example, a light emitting diode (LED) or a xenon lamp. In some embodiments, two or more lenses (an IR camera, a wide-angle lens, and a telephoto lens) and image sensors may be arranged on one surface of the electronic device 200.

According to an embodiment, the key input devices 217 may be arranged on the side surface 210C of the housing 210. In another embodiment, the electronic device 200 may not include some or any of the key input devices 217, and the key input devices 217 which are not included may be implemented in other forms such as soft keys on the display 220. According to an embodiment, at least some of the key input devices may be disposed on the side bezel structure 218.

According to an embodiment, the light emitting element (not shown) may be disposed, for example, on the front surface 210A of the housing 210. The light emitting element (not shown) may provide, for example, state information about the electronic device 200 in the form of light. In another embodiment, the light emitting element (not shown) may provide, for example, a light source interworking with an operation of the front camera module 205. The light emitting element (not shown) may include, for example, an LED, an IR LED, and/or a xenon lamp.

According to an embodiment, the connector holes 208 and 209 may include a first connector hole 208 capable of accommodating a connector (e.g., a USB connector) for transmitting and receiving power and/or data to and from an external electronic device and/or a second connector hole 209 capable of accommodating a storage device (e.g., a subscriber identification module (SIM) card). According to an embodiment, the first connector hole 208 and/or the second connector hole 209 may be omitted.

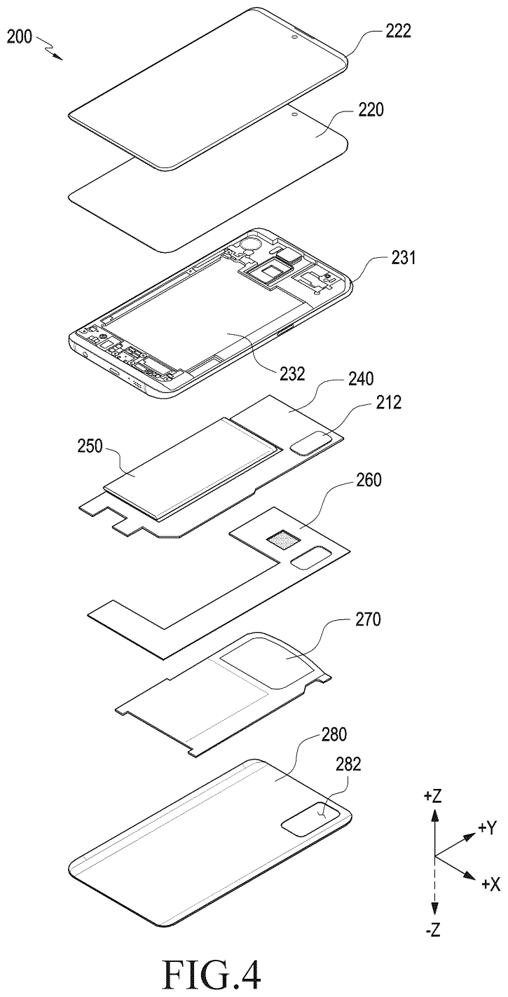

FIG. 4 is an exploded perspective view illustrating an electronic device according to an embodiment of the disclosure.

Referring to FIG. 4, the electronic device 200 (e.g., the electronic device 200 of FIGS. 2 and 3) may include at least one of a front plate 222 (e.g., the front plate 202 of FIG. 2), the display 220 (e.g., the display 220 of FIG. 2), a bracket 232 (e.g., a front support member), a PCB 240, a battery 250, a rear case 260 (e.g., a rear support member), an antenna 270, or a rear plate 280 (e.g., the rear plate 211 of FIG. 3). According to an embodiment, the electronic device 200 may not be provided with at least one (e.g., the rear case 260) of the components or may additionally include other components. At least one of the components of the electronic device 200 may be the same as or similar to at least one of the components of the electronic device 200 of FIG. 2 or FIG. 3, and a redundant description will be avoided herein.

According to various embodiments, the bracket 232 may be disposed inside the electronic device 200 and connected to a side bezel structure 231, or may be integrally formed with the side bezel structure 231. The bracket 232 may be formed of, for example, a metal material and/or a non-metal (e.g., polymer) material. The bracket 232 may accommodate the display 220 on one surface thereof and the PCB 240 on the other surface thereof. A processor (e.g., the processor 120 of FIG. 1), memory (e.g., the memory 130 of FIG. 1), and/or an interface (e.g., the interface 177 of FIG. 1) may be mounted on the PCB 240.

According to an embodiment, the battery 250, which is a device for supplying power to at least one component of the electronic device 200, may include, for example, a non-rechargeable primary cell, a rechargeable secondary cell, or a fuel cell. At least a portion of the battery 250 may be disposed substantially on the same plane with the PCB 240, for example. The battery 250 may be disposed integrally inside the electronic device 200 or disposed detachably from the electronic device 200.

According to various embodiments, the rear case 260 may be disposed between the PCB 240 and the antenna 270. For example, the rear case 260 may include one surface coupled to or facing at least one of the PCB 240 or the battery 250 and the other surface coupled to or facing the antenna 270.

According to an embodiment, the antenna 270 may be disposed between the rear plate 280 and the battery 250. The antenna 270 may include, for example, a near field communication (NFC) antenna, a wireless charging antenna, and/or a magnetic secure transmission (MST) antenna. The antenna 270 may, for example, perform short-range communication with an external device or wirelessly transmit and receive power for charging to and from an external device. For example, the antenna 270 may include a coil for wireless charging. In an embodiment, an antenna structure may be formed by a portion or combination of the side bezel structure 231 and/or the bracket 232.

According to an embodiment, the electronic device 200 may include a camera module 212 disposed within the housing (e.g., the housing 210 of FIG. 2). According to an embodiment, the camera module 212 may be disposed on the bracket 232, and may be a rear camera module (e.g., the camera module 212 of FIG. 3). According to an embodiment, at least a portion of the camera module 212 may be exposed to the outside of the electronic device 200 through an opening 282 formed on the rear plate 280.

The electronic device 200 disclosed in FIGS. 2 to 4 has a bar-type or plate-type appearance, to which the disclosure is not limited. For example, the illustrated electronic device may be a rollable electronic device or a foldable electronic device. The term “rollable electronic device” may refer to an electronic device in which a display (e.g., the display 220 of FIG. 4) is bendable, so that at least a portion thereof is wound or rolled or is accommodated into a housing (e.g., the housing 210 of FIG. 2). Depending on the needs of a user, the rollable electronic device may be used by unfolding a display or exposing a wider area of the display to the outside to extend a screen display area.

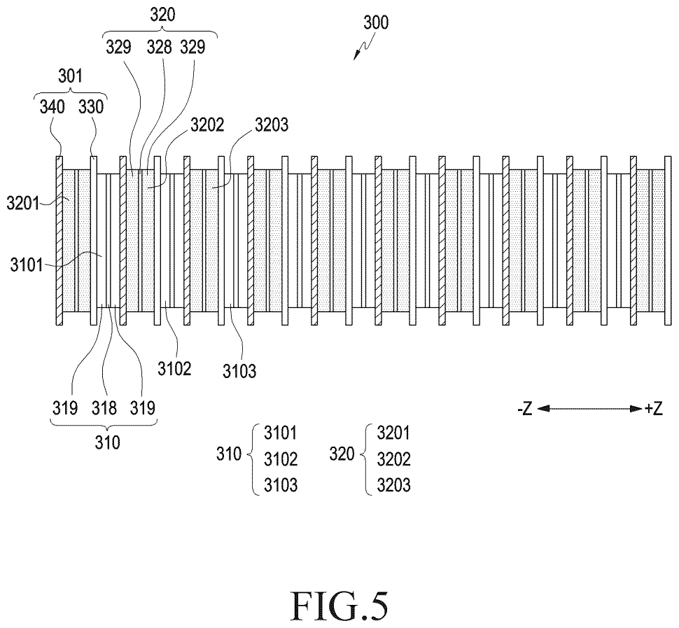

FIG. 5 is a schematic diagram illustrating a battery according to an embodiment of the disclosure.

Referring to FIG. 5, a battery 300 may include a cathode 310, an anode 320, and a separator 301. The configuration of the battery 300 in FIG. 5 may be wholly or partially the same as the configuration of the battery 189 in FIG. 1 or the battery 250 in FIG. 4.

According to an embodiment, the battery 300 may supply power to at least one component of an electronic device (e.g., the electronic device 200 in FIG. 2) (e.g., a mobile phone). The battery 300 may be a rechargeable secondary battery. According to an embodiment, the battery 300 may be disposed within the electronic device 200.

According to an embodiment, the cathode 310 may include a plurality of second electrodes 3101, 3102, and 3103 spaced apart from each other. According to an embodiment, the number of cathodes 310 may vary based on the design of the battery 300. According to an embodiment, the cathode 310 may be referred to as a positive electrode or a second electrode.

According to an embodiment, the cathode 310 may include a positive electrode substrate 318 and a positive electrode mixture 319 disposed on the positive electrode substrate 318. Each of the plurality of second electrodes 3101, 3102, and 3103 may include a positive electrode substrate 318 and a positive electrode mixture 319. For example, one of the plurality of second electrodes 3101, 3102, and 3103 may include one positive electrode substrate 318 and two positive electrode mixtures 319. In an embodiment, the positive electrode substrate 318 may include aluminum (Al). In an embodiment, the positive electrode mixture 319 may include lithium (Li) oxide including a transition metal (e.g., at least one of cobalt (Co), manganese (M n), or iron (Fe)). The positive electrode mixture 319 may include a positive electrode active material, a conductive agent, and a binder. According to an embodiment, the positive electrode mixture 319 may surround at least a portion of the positive electrode substrate 318. For example, the positive electrode substrate 318 may be disposed between a pair of positive electrode mixtures 319. According to an embodiment, the positive electrode substrate 318 may be referred to as a second substrate, and the positive electrode mixture 319 may be referred to as a second mixture.

According to an embodiment, the anode 320 may include a plurality of first electrodes 3201, 3202, and 3203. According to an embodiment, the number of anodes 320 may vary based on the design of the battery 300. According to an embodiment, the anode 320 may be referred to as a negative electrode or a first electrode.

According to an embodiment, the cathode 310 and the anode 320 may be stacked relative to each other. For example, the plurality of second electrodes 3101, 3102, and 3103 and the plurality of first electrodes 3201, 3202, and 3203 may be alternately arranged one by one.

According to an embodiment, the anode 320 may include a negative electrode substrate 328 and a negative electrode mixture 329. Each of the plurality of first electrodes 3201, 3202, and 3203 may include a negative electrode substrate 328 and a negative electrode mixture 329. For example, one of the plurality of first electrodes 3201, 3202, and 3203 may include one negative electrode substrate 328 and two negative electrode mixtures 329. According to an embodiment, the negative electrode substrate 328 may include nickel (Ni) and/or copper (Cu). According to an embodiment, the negative electrode mixture 329 may include graphite and/or Li—Ti oxide. The negative electrode mixture 329 may include a negative electrode active material, a conductive agent, and a binder. According to an embodiment, the negative electrode mixture 329 may surround at least a portion of the negative electrode substrate 328. For example, the negative electrode substrate 328 may be located between a pair of negative electrode mixtures 329. In an embodiment, the negative electrode substrate 328 may be referred to as a first substrate, and the negative electrode mixture 329 may be referred to as a first mixture.

According to an embodiment, the separator 301 may be a non-conductive porous body having pores, which physically separates the cathode 310 and the anode 320 from each other and allows the movement of a specified substance (e.g., Li ions). According to an embodiment, the separator 301 may be a synthetic resin (e.g., polyethylene or polypropylene).

According to an embodiment, the separator 301 may be provided as a plurality of separators. For example, the separator 301 may include a first separator 330 and a second separator 340. The second separator 340 may be spaced apart from the first separator 330.

According to an embodiment, the battery 300 may have a stacked shape. For example, the cathode 310, the anode 320, the first separator 330, and the second separator 340 may have a stacked shape. According to an embodiment, one (e.g., the second separator 340) of the separators 301, one (e.g., the first electrode 3201) of the plurality of anodes 320, one (e.g., the second electrode 3101) of the plurality of cathodes 310, and the other one (e.g., the first separator 330) of the separators 301 may be stacked in sequence. According to an embodiment, the battery 300 may be a stack type battery.

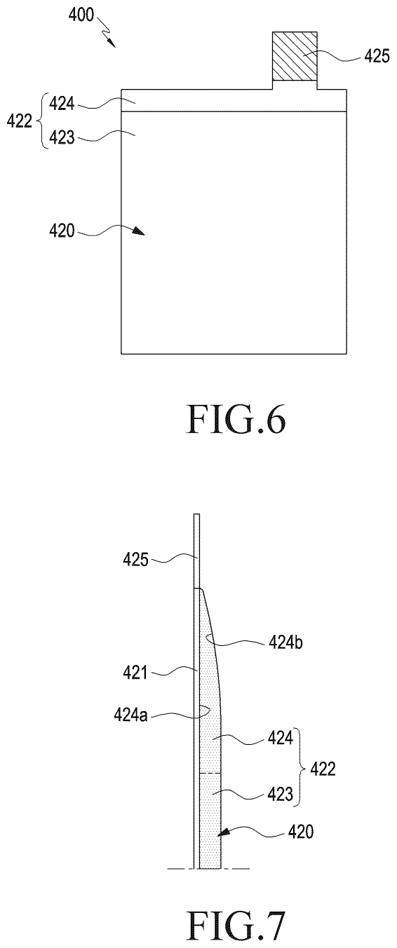

FIG. 6 is a front view illustrating a battery according to an embodiment of the disclosure.

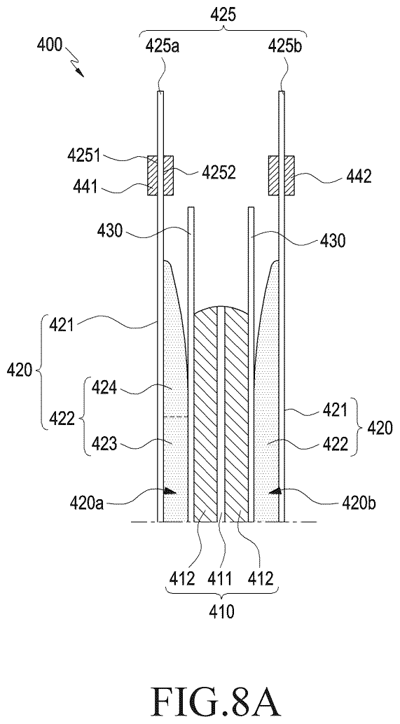

FIG. 7 is a side view illustrating a battery according to an embodiment of the disclosure.

Referring to FIGS. 6 and 7, a battery 400 may include an anode 420. The anode 420 may include a negative electrode substrate 421 and a negative electrode mixture 422. The configurations of the battery 400, the anode 420, the negative electrode substrate 421, and the negative electrode mixture 422 in FIGS. 6 and 7 may be wholly or partially the same as the configurations of the battery 300, the anode 320, the negative electrode substrate 328, and the negative electrode mixture 329 in FIG. 5.

According to an embodiment, the negative electrode mixture 422 may be disposed on the negative electrode substrate 421. The negative electrode mixture 422 may surround at least a portion of the negative electrode substrate 421. For example, in an embodiment, the negative electrode mixture 422 may be formed by being coated on the negative electrode substrate 421. As the fluid-state negative electrode mixture 422 flows, an end portion (e.g., an end area 424) of the negative electrode mixture 422 may have partially different thicknesses.

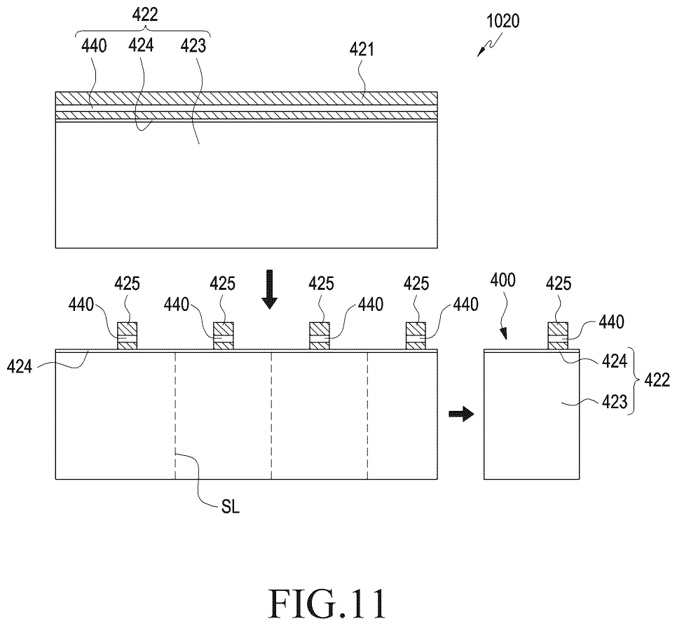

In the specification, the structure of the negative electrode mixture 422 is shown as including one end area 424 by using a slitting line (e.g., a slitting line SL in FIG. 11), to which the structure of the negative electrode mixture 422 is not limited. For example, the negative electrode mixture 422 may include at least one end area 424. The negative electrode mixture 422 may be formed by coating liquid slurry. Due to the surface tension of the liquid slurry, at least a portion (e.g., the end area 424) of an edge of the negative electrode mixture 422 may have a slanted shape or a shape with a varying thickness. According to an embodiment, the end area 424 may be referred to as a sliding area.

According to an embodiment, the negative electrode mixture 422 of the anode 420 may have partially different thicknesses. The negative electrode mixture 422 may include a flat area 423 and the end area 424 extending from the flat area 423. The end area 424 may form at least a portion of the edge of the negative electrode mixture 422. For example, the end area 424 may be closer to a negative electrode tab 425 than the flat area 423.

The end area 424 may be removed by etching, notching, and/or cutting. However, when the end area 424 is removed, loss of an electrode (e.g., the negative electrode mixture 422) and/or poor welding of the tab may occur. When a post-process is used to apply pressure to the flat area 423, a cell-to-cell variation may be large and electrode plate deterioration may occur.

According to an embodiment, the flat area 423 may have a substantially uniform thickness. The end area 424 may have a gradually changing thickness. For example, the end area 424 may include a first surface 424a in contact with the negative electrode substrate 421 and a second surface 424b which is at least partially curved. The thickness of the end area 424 may be less than or equal to the thickness of the flat area 423. According to an embodiment, the second surface 424b may face in an opposite direction to the first surface 424a. For example, the second surface 424b may be a portion of the end area 424 extending from the first surface 424a.

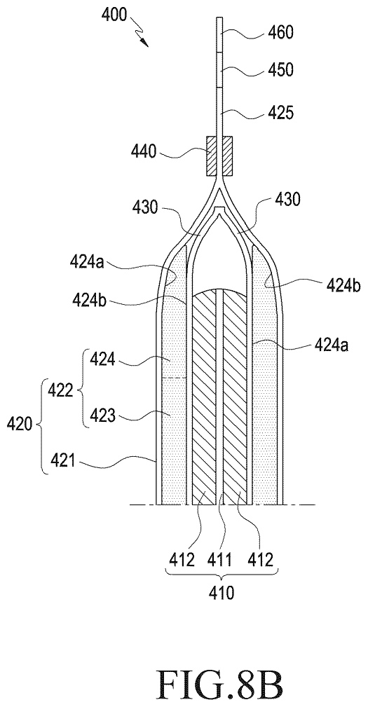

According to an embodiment, the battery 400 may include the negative electrode tab 425. The negative electrode tab 425 may be electrically connected to the anode 420. For example, the negative electrode tab 425 may be a portion of the battery 400, which extends from the negative electrode substrate 421. The negative electrode tab 425 may be referred to as a first tab. The negative electrode tab 425 may be connected to a negative electrode lead 460 (e.g., the negative electrode lead 460 in FIG. 8B). Power generated from the battery 400 may be transmitted to an electronic device external to the battery 400 using the negative electrode tab 425 and the negative electrode lead 460.

FIGS. 8A and 8B are side views illustrating a battery including an adhesive according to various embodiments of the disclosure. For example, FIG. 8A is a schematic diagram illustrating a battery including a plurality of negative electrode tabs 425 spaced apart from each other. FIG. 8B is a schematic diagram illustrating a battery including a plurality of coupled negative electrode tabs 425.

Referring to FIGS. 8A and/or 8B, the battery 400 may include a cathode 410, the anode 420, a separator 430, an adhesive 440, and a coupling portion 450. The configurations of the battery 400, the cathode 410, the anode 420, and the separator 430 in FIGS. 8A and/or 8B may be wholly or partially the same as the configurations of the battery 300 or 400, the cathode 310, the anode 320 or 420, and the separator 301 in FIGS. 5, 6, and/or 7.

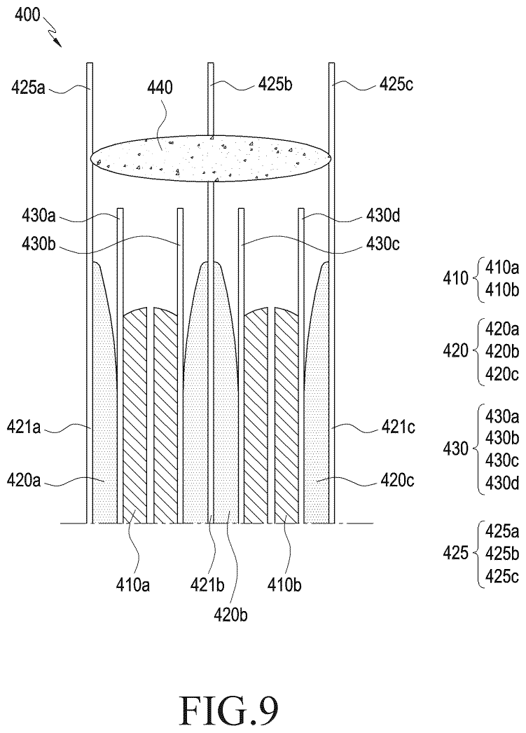

According to an embodiment, the negative electrode tab 425 may include a plurality of negative electrode tabs 425a and 425b each connected to the anode 420. For example, the negative electrode tab 425 may include a (2-1)th negative electrode tab 425a connected to a first negative electrode substrate 421a (e.g., the first negative electrode substrate 421a in FIG. 9) and a (2-2)th negative electrode tab 425b connected to a second negative electrode substrate 421b (e.g., the second negative electrode substrate 421b in FIG. 9) and a (2-3)th negative electrode tab 425c connected to a third negative electrode substrate 421c (e.g., the third negative electrode substrate 421c in FIG. 9). The number of negative electrode tabs 425 is optional. For example, referring to FIG. 9, the battery 400 may include three or more negative electrode tabs 425. Each negative electrode tab 425 may be connected to a different negative electrode substrate 421.

According to an embodiment, the adhesive 440 may be disposed on at least a portion of the negative electrode tab 425. For example, the negative electrode tab 425 may include a top surface 4251 and a rear surface 4252 opposite to the top surface 4251. The adhesive 440 may be coated on portions of the top surface 4251 of the negative electrode tab 425 and the rear surface 4252 of the negative electrode tab 425.

According to an embodiment, the battery 400 may include the coupling portion 450 connecting a plurality of negative electrode tabs (e.g., the (2-1)^{th} negative electrode tab 425a and the (2-2)^{th} negative electrode tab 425b). For example, the coupling portion 450 may connect or combine the (2-1)^{th} negative electrode tab 425a and the (2-2)^{th} negative electrode tab 425b. The coupling portion 450 may be a portion in which the plurality of negative electrode tabs (e.g., the (2-1)^{th} negative electrode tab 425a and the (2-2)^{th} negative electrode tab 425b) are welded or combined. According to an embodiment, the plurality of negative electrode tabs (e.g., the (2-1)^{th} negative electrode tab 425a and the (2-2)^{th} negative electrode tab 425b) may be connected by the adhesive 440 and the coupling portion 450.

According to an embodiment, the adhesive 440 may bring the cathode 410, the anode 420, and the separator 430 into close contact. For example, the adhesive 440 may be attached to the negative electrode tab 425. The adhesive 440 may connect the plurality of negative electrode tabs (e.g., the (2-1)^{th} negative electrode tab 425a and the (2-2)^{th} negative electrode tab 425b). As the adhesive 440 connects the plurality of negative electrode tabs (e.g., the (2-1)^{th} negative electrode tab 425a and the (2-2)^{th} negative electrode tab 425b) to each other, the tension of the negative electrode substrate 421 of the anode 420 may be increased. During stacking and assembly of the battery 400, for example, a portion of the negative electrode tab 425 where the adhesive 440 is located may be thermally compressed, the adhesive strength of the adhesive 440 may be increased, and a tensile force may be applied to the negative electrode tab 425. Due to the adhesive 440, an empty space between the positive electrode mixture 412 of the cathode 410 and the separator 430 and an empty space between the negative electrode mixture 422 of the anode 420 and the separator 430 may be reduced. A contact area between the negative electrode mixture 422 and the separator 430 and a contact area between the positive electrode mixture 412 and the separator 430 may be increased due to the adhesive 440. As the cathode 410, the anode 420, and the separator 430 are in close contact, a movement path of ions (e.g., Li ions) of the battery 400 may be reduced, a current density may be uniformly formed, and the stability, lifespan, charging efficiency, and energy density of the battery 400 against heat and shock may be increased.

According to an embodiment, the adhesive 440 may include a first adhesive 441 and a second adhesive 442. The first adhesive 441 may be disposed on the first negative electrode tab 425a of a first anode 420a, and the second adhesive 442 may be disposed on the second negative electrode tab 425b of a second anode 420b spaced apart from the first anode 420a. When the plurality of negative electrode tabs 425a and 425b are coupled at the coupling portion 450, the first adhesive 441 and the second adhesive 442 may adhere to each other. For example, a portion of the first adhesive 441 facing the second adhesive 442 may be combined with the second adhesive 442.

Referring to FIG. 8B, the anode 420 may be in close contact with the separator 430. For example, the end area 424 of the anode 420 may be in contact with the negative electrode substrate 421 and the separator 430. At least a portion of the first surface 424a of the end area 424 of the anode 420 may be in contact with the negative electrode substrate 421, and at least a portion of the second surface 424b may be in contact with the separator 430. At least a portion of the end area 424 may have a curved shape. For example, at least a portion of the first surface 424a and/or at least a portion of the second surface 424b may be curved.

According to an embodiment, the adhesive 440 may be spaced apart from the negative electrode mixture 422 of the anode 420. According to an embodiment, the adhesive 440 may be located between the coupling portion 450 of the negative electrode tab 425 and the negative electrode mixture 422.

The adhesive 440 may be disposed on a portion of the negative electrode tab 425. According to an embodiment, the adhesive 440 may be coated on at least a portion of the negative electrode tab 425. According to an embodiment, the adhesive 440 may be applied or sprayed in a fluid state on at least a portion of the negative electrode tab 425.

According to an embodiment, the thickness of the adhesive 440 may be less than or equal to the thickness of the negative electrode mixture 422. As the adhesive 440 is formed to have a thickness less than or equal to the thickness of the negative electrode mixture 422, the assemblability of the battery 400 may be improved.

According to an embodiment, the adhesive 440 may be made of an electrolyte resistant material. For example, the adhesive 440 may include polyvinylidene fluoride (PV DF), an acrylate polymer, rubber, and/or an adhesive resin.

FIG. 9 is a side view illustrating a battery including a plurality of adhesives according to an embodiment of the disclosure.

Referring to FIG. 9, the battery 400 may include the cathode 410, the anode 420, the separator 430, and the adhesive 440. The configurations of the battery 400, the cathode 410, the anode 420, the separator 430, and the adhesive 440 in FIG. 9 may be wholly or partially the same as the configurations of the battery 400, the cathode 410, the anode 420, the separator 430, and the adhesive 440 in FIG. 8A or 8B.

According to an embodiment, the battery 400 may be a stack type battery. For example, the battery 400 may include the cathode 410, the anode 420, and the separator 430 which are stacked. For example, the cathode 410 may include a plurality of cathodes 410a and 410b. For example, the cathode 410 may include a first cathode 410a and a second cathode 410b spaced apart from the first cathode 410a. The anode 420 may include a plurality of anodes 420a, 420b, and 420c. For example, the anode 420 may include a first anode 420a, a second anode 420b spaced apart from the first anode 420a, and a third anode 420c spaced apart from the second anode 420b. The separator 430 may include a plurality of separators 430a, 430b, 430c, and 430d. For example, the separator 430 may include a first separator 430a located between the first cathode 410a and the first anode 420a, a second separator 430b located between the first cathode 410a and the second anode 420b, a third separator 430c located between the second anode 420b and the second cathode 410b, and a fourth separator 430d located between the second cathode 410b and the third anode 420c. The numbers of cathodes 410 and anodes 420 included in the battery 400 are optional. For example, the number of the plurality of cathodes included in the cathode 410 and the number of the plurality of anodes included in the anode 420 may vary depending on the size and/or capacity of the battery 400.

According to an embodiment, the adhesive 440 may be injected into the multi-layer stacked battery 400. According to an embodiment (e.g., FIG. 9), the adhesive 440 may include a conductive paste. For example, the adhesive 440 may include a conductive ink and/or a binder. The adhesive 440, which is a conductive paste, may couple the plurality of negative electrode tabs 425. For example, the plurality of negative electrode tabs 425a, 425b, and 425c may be coupled by the adhesive 440 and a coupling portion (e.g., the coupling portion 450 in FIG. 8B). According to an embodiment (not shown), the coupling portion 450 may be excluded, and the adhesive 440 may bind the plurality of negative electrode tabs 425. According to an embodiment, the plurality of negative electrode tabs 425 may be coupled with respect to one electrode tab (e.g., the second negative electrode tab 425b).

According to an embodiment (not shown), the adhesive 440 may be arranged to correspond to the coupling of the plurality of negative electrode tabs 425. For example, a position at which the adhesive 440 is disposed on the negative electrode tab 425 may be changed according to the design of the battery 400. According to an embodiment, the adhesive 440 may have a width for connection. A plurality of adhesives 440 may be arranged to overlap each other. According to an embodiment (not shown), the distance between an adhesive 440 attached to a negative electrode tab (e.g., the second negative electrode tab 425b in FIG. 9) located at the center and a negative electrode mixture (e.g., the negative electrode mixture 422 in FIG. 8B) may be smaller than the distance between an adhesive 440 attached to a negative electrode tab (e.g., the first negative electrode tab 425a and/or the second negative electrode tab 425b in FIG. 9) and the negative electrode mixture 422.

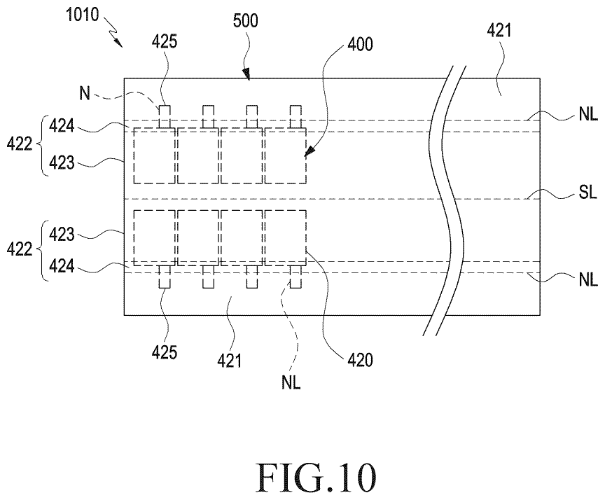

FIGS. 10 and 11 are diagrams illustrating a process of manufacturing a battery according to various embodiments of the disclosure. For example, FIG. 10 is a diagram 1010 illustrating a process of manufacturing a battery by slitting and notching. FIG. 11 is a diagram 1020 illustrating a process of manufacturing the battery 400 including the negative electrode tab 425 on which the adhesive 440 is located.

Referring to FIGS. 10 and/or 11, the battery 400 may include the anode 420 including the negative electrode substrate 421 and the negative electrode mixture 422, and the adhesive 440.

The configurations of the battery 400, the negative electrode substrate 421, the negative electrode mixture 422, and the adhesive 440 in FIGS. 10 and/or 10 may be wholly or partially the same as the configurations of the battery 400, the negative electrode substrate 421, the negative electrode mixture 422, and the adhesive 440 in FIGS. 8A and/or 8B. For example, the battery 400 in FIG. 8B may be manufactured by the process of manufacturing a battery in FIGS. 10 and/or 11.

According to an embodiment (e.g., FIG. 10), the negative electrode tab 425 may be a portion from which the negative electrode substrate 421 has been removed. A portion of the negative electrode substrate 421 where the negative electrode mixture 422 is not located may be referred to as an uncoated portion. The negative electrode tab 425 may extend from the negative electrode substrate 421. For example, the uncoated portion of the negative electrode substrate 421 may be cut by a notching process. At least a portion of the uncoated portion may be removed along a notching line NL, and a portion of the uncoated portion which is not removed may be referred to as the negative electrode tab 425. The notching process may be performed using a laser and/or a cutting tool (e.g., a press device).

According to an embodiment, an electrode plate 500 may be cut into a plurality of electrodes (e.g., anodes 420) using a slitting process. For example, the electrode plate 500 may be cut into the plurality of anodes 420 along the slitting line SL. The slitting line SL may be selectively changed according to the design of the battery 400. The electrode plate 500 may be an electrode formed using a roll pressing process.

According to an embodiment, the adhesive 440 may be disposed on the negative electrode substrate 421. For example, the adhesive 440 may be coated on a surface of the negative electrode substrate 421.

According to an embodiment, the adhesive 440 may be cut together with the negative electrode substrate 421. For example, the adhesive 440 and the negative electrode substrate 421 may be cut along the notching line NL. The adhesive 440 may be spaced apart from the negative electrode mixture 422.

In the specification, the battery 400 including the adhesive 440 located on the negative electrode tab 425 has been described. However, the position where the adhesive 440 is disposed is not limited to the negative electrode tab 425. For example, in an embodiment, the adhesive 440 may be disposed on a positive electrode tab (e.g., a second tab). The adhesive disposed on the positive electrode tab may be spaced apart from the positive electrode mixture (e.g., the positive electrode mixture 319 in FIG. 5). For example, the adhesive disposed or coated on the positive electrode tab may be located between the positive electrode mixture 319 and a coupling portion of the positive electrode tab. According to an embodiment, the adhesive 440 may be disposed on the positive electrode tab as well as the negative electrode tab 425.

A secondary battery (e.g., a lithium ion battery) may include an electrode assembly including a cathode (e.g., a positive electrode), an anode (e.g., a negative electrode), and a separator. The cathode and the anode may store or supply Li ions. The separator may prevent contact between the cathode and the anode, thereby preventing the short circuit of the battery.

The cathode, the separator, and the anode may be brought into close contact through an assembly and chemical process (e.g., activation process). As the empty space among the cathode, the separator, and the anode is reduced, the movement path of Li ions is reduced, and the current density may become uniform. However, an edge portion (e.g., end area) of an electrode may have an uneven thickness due to the surface tension of liquid slurry.

When the end area of the electrode has an uneven thickness, the electrode and the separator may be separated, and the battery may be deformed. In particular, when the end area of the anode or the cathode is separated from the separator, the electrode interface resistance may increase, thereby reducing the durability of the battery. When a portion of the electrode is cut to uniformly form the thickness of the end area, an additional process may be required, and electrode loss and tab welding failure may occur.

According to an embodiment of the disclosure, an electronic device may be provided which maintains contact between an edge portion (e.g., end area) of an electrode (e.g., an anode) and a separator, thereby preventing electrode plate deterioration, improving battery durability, and increasing the lifespan of a battery.

The problems to be solved in the disclosure are not limited to the problem mentioned above, and may be expanded in various ways without departing from the scope and spirit of the disclosure.

In addition, various effects that are directly or indirectly identified from the specification may be provided.

According to an embodiment of the disclosure, an electronic device (e.g., the electronic device 200 in FIG. 2) may include a processor (e.g., the processor 120 in FIG. 1) and a battery (e.g., the battery 189 in FIG. 1, the battery 250 in FIG. 4, the battery 300 in FIG. 5, and/or the battery 400 in FIG. 6) configured to supply power to the processor. The battery may include a second electrode (e.g., the cathode 310 in FIG. 5), a first electrode (e.g., the anode 320 in FIG. 5 and/or the anode 420 in FIG. 6), a separator (e.g., the separator 301 in FIG. 5 and/or the separator 430 in FIG. 8A) configured to prevent contact between the first electrode and the second electrode, a first tab (e.g., the negative electrode tab 425 in FIG. 6) connected to the first electrode, and an adhesive (e.g., the adhesive 440 in FIG. 8A) disposed on at least a portion of the first tab. The first electrode may include a first substrate (e.g., the negative electrode substrate 421 in FIG. 8A) and a first mixture (e.g., the negative electrode mixture 422 in FIG. 8A) surrounding at least a portion of the first substrate and spaced apart from the adhesive. The adhesive may be located between a coupling portion (e.g., the coupling portion 450 in FIG. 8B) of the first tab and the first mixture. As the adhesive is located between the junction and the first mixture, a tensile force may be applied to the first tab and the first mixture. An empty space between the first mixture and the separator may be reduced, and the cathode, the separator, and the first electrode may be brought into close contact with each other.

Although the first electrode has been described as an anode in the disclosure, the first electrode may be a cathode, and the second electrode may be an anode in another embodiment. For example, in an embodiment, the adhesive may be disposed on at least a portion of a tab of a positive electrode (cathode).

According to an embodiment, the first mixture may include a flat area (e.g., the flat area 423 in FIG. 8A) and an end area (e.g., the end area 424 in FIG. 8A) extending from the flat area and having a gradually changing thickness.

According to an embodiment, the end area may contact the first substrate and the separator.

According to an embodiment, the end area may include a first surface (e.g., the first surface 424a in FIG. 8B) contacting the first substrate, and a second surface (e.g., the second surface 424b in FIG. 8B) at least partially curved and contacting the separator.

According to an embodiment, the first tab may include a top surface and a rear surface opposite to the top surface. The adhesive may be coated on the top surface and/or the rear surface.

According to an embodiment, the adhesive may include at least one of polyvinylidene fluoride, acrylate, rubber, or an adhesive resin.

According to an embodiment, the first electrode includes a (1-1)^{th} electrode (e.g., the first anode 420a in FIG. 9) and a (1-2)^{th} electrode (e.g., the second anode 420b in FIG. 9). The adhesive may include a first adhesive (e.g., the first adhesive 441 in FIG. 8A) attached to a (1-1)^{th} tab (e.g., the first negative electrode tab 425a in FIG. 8A) of the (1-1)^{th} electrode and a second adhesive (e.g., the second adhesive 442 in FIG. 8A) attached to a (1-2)^{th} tab (e.g., the second negative electrode tab 425b in FIG. 8A) of the (1-2)^{th} electrode 420b. The first adhesive may be coupled with the second adhesive.

According to an embodiment, a thickness of the adhesive may be smaller than or equal to a thickness of the first mixture.

According to an embodiment, the first substrate may include at least one of nickel or copper. The first mixture may include at least one of graphite or lithium-titanium oxide.

According to an embodiment, the separator may include a non-conductive porous body including pores.

According to an embodiment, the adhesive may include a conductive ink or a binder. The first tab may include a plurality of first tabs (e.g., the first negative electrode tab 425a, the second negative electrode tab 425b, and the third negative electrode tab 425c in FIG. 9) connected using the adhesive.

According to an embodiment, the second electrode may include a second substrate (e.g., the positive electrode substrate 318 in FIG. 5) and a second mixture (e.g., the positive electrode mixture 319 in FIG. 5) surrounding at least a portion of the second substrate.

According to an embodiment, the second substrate may include aluminum. The second mixture may include lithium oxide.

According to an embodiment, the adhesive may be configured to provide a tensile force to the second substrate and a second tab. As a tensile force is provided to the second substrate and the second tab, the cathode and the separator may be in closer contact with each other.

According to an embodiment of the disclosure, a battery may include a second electrode (e.g., the cathode 310 in FIG. 5), a first electrode (e.g., the anode 320 in FIG. 5 and/or the anode 420 in FIG. 6), a separator (e.g., the separator 301 in FIG. 5 and/or the separator 430 in FIG. 8A) configured to prevent contact between the first electrode and the second electrode, a first tab (e.g., the negative electrode tab 425 in FIG. 6) connected to the first electrode, and an adhesive (e.g., the adhesive 440 in FIG. 8A) disposed on at least a portion of the first tab. The first electrode may include a first substrate (e.g., the negative electrode substrate 421 in FIG. 8A) and a first mixture (e.g., the negative electrode mixture 422 in FIG. 8A) surrounding at least a portion of the first substrate and spaced apart from the adhesive. The adhesive may be located between a coupling portion (e.g., the coupling portion 450 in FIG. 8B) of the first tab and the first mixture.

The battery and the electronic device including the battery according to the disclosure described above are not limited to the foregoing embodiment and drawings, and it will be apparent to those skilled in the art that many replacements, variations, and modifications may be made within the scope of the disclosure.

While the disclosure has been shown and described with reference to various embodiments thereof, it will be understood by those skilled in the art that various changes in form and details may be made therein without departing from the spirit and scope of the disclosure as defined by the appended claims and their equivalents.

What is claimed is:

1. An electronic device comprising:
a processor; and
a battery configured to supply power to the processor,
wherein the battery includes:
a first electrode,
a second electrode,
a separator configured to prevent contact between the first electrode and the second electrode,
a first tab connected to the first electrode, and
an adhesive disposed on at least a portion of the first tab,
wherein the first electrode includes:
a first substrate, and
a first mixture surrounding at least a portion of the first substrate and spaced apart from the adhesive, and
wherein the adhesive is located between a coupling portion of the first tab and the first mixture.

2. The electronic device of claim 1, wherein the first mixture includes:
a flat area; and
an end area extending from the flat area and having a thickness which gradually changes.

3. The electronic device of claim 2, wherein the end area contacts the first substrate and the separator.

4. The electronic device of claim 2, wherein the end area includes:
a first surface contacting the first substrate; and
a second surface at least partially curved and contacting the separator.

5. The electronic device of claim 1,
wherein the first tab includes:
a top surface, and
a rear surface opposite to the top surface, and
wherein the adhesive is coated on at least one of the top surface or the rear surface.

6. The electronic device of claim 1, wherein the adhesive includes at least one of polyvinylidene fluoride, acrylate, rubber, or an adhesive resin.

7. The electronic device of claim 1,
wherein the first electrode includes:
a (1-1)^{th} electrode; and
a (1-2)^{th} electrode,
wherein the adhesive includes:
a first adhesive attached to a (1-1)^{th} tab of the (1-1)^{th} electrode, and
a second adhesive attached to a (1-2)^{th} tab of the (1-2)^{th} electrode, and
wherein the first adhesive is coupled to the second adhesive.

8. The electronic device of claim 1, wherein a thickness of the adhesive is smaller than or equal to a thickness of the first mixture.

9. The electronic device of claim 1,
wherein the first substrate includes at least one of nickel or copper, and
wherein the first mixture includes at least one of graphite or lithium-titanium oxide.

10. The electronic device of claim 1, wherein the separator includes a non-conductive porous body including pores.

11. The electronic device of claim 1,
wherein the adhesive includes a conductive ink or a binder, and
wherein the first tab includes a plurality of first tabs connected using the adhesive.

12. The electronic device of claim 1,
wherein the second electrode includes:
a second substrate, and
a second mixture surrounding at least a portion of the second substrate, and
wherein the battery further includes a second tab connected to the second electrode.

13. The electronic device of claim 12,
wherein the second substrate includes aluminum, and
wherein the second mixture includes lithium oxide.

14. The electronic device of claim 12,
wherein the adhesive is disposed on at least a portion of the second tab, and
wherein the adhesive is spaced apart from the second mixture.

15. A battery comprising:
a first electrode;
a second electrode;
a separator configured to prevent contact between the first electrode and the second electrode;
a first tab connected to the first electrode; and
an adhesive disposed on at least a portion of the first tab,
wherein the first electrode includes:
a first substrate, and
a first mixture surrounding at least a portion of the first substrate and spaced apart from the adhesive, and
wherein the adhesive is located between a coupling portion of the first tab and the first mixture.

16. The battery of claim 15, wherein the first mixture includes:
a flat area; and
an end area extending from the flat area and having a thickness which gradually changes.

17. The battery of claim 16, wherein the end area contacts the first substrate and the separator.

18. The battery of claim 16, wherein the end area includes:
a first surface contacting the first substrate; and
a second surface at least partially curved and contacting the separator.

19. The battery of claim 16,
wherein the first tab includes:
a top surface, and
a rear surface opposite to the top surface, and
wherein the adhesive is coated on at least one of the top surface or the rear surface.

20. The battery of claim 16, wherein the adhesive includes at least one of polyvinylidene fluoride, acrylate, rubber, or an adhesive resin.
